(19) United States
(12) Patent Application Publication
(10) Pub. No.: US 2026/0089958 A1
(43) Pub. Date: Mar. 26, 2026

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventors: Weon Guk KIM, Icheon-si Gyeonggi-do (KR); Jeong Seob OH, Icheon-si Gyeonggi-do (KR)

(73) Assignee: SK hynix Inc., Icheon-si Gyeonggi-do (KR)

(21) Appl. No.: 19/042,297

(22) Filed: Jan. 31, 2025

(30) Foreign Application Priority Data
Sep. 25, 2024 (KR) 10-2024-0130218

(51) Int. Cl. H10B 43/30; H10B 41/27; H10B 41/30; H10B 43/27

(52) U.S. Cl. CPC H10B 43/30; H10B 41/27; H10B 41/30; H10B 43/27

(57) ABSTRACT

A semiconductor device includes a support structure including first insulating layers alternately stacked with second insulating layers, a gate structure including conductive layers and including a first section positioned at a level corresponding to a level of the support structure and a second section positioned on the support structure, a contact plug extending through the gate structure and connected to a first conductive layer of the conductive layers, and a first support including pillars extending between the first section and the support structure and extending through the second section, and first protrusions protruding from the pillars into the support structure.

### CROSS-REFERENCE TO RELATED APPLICATION

The present application claims priority under 35 U.S.C. § 119(a) to Korean Patent Application No. 10-2024-0130218, filed in the Korean Intellectual Property Office on Sep. 25, 2024, which application is incorporated herein by reference in its entirety.

### BACKGROUND

### 1. Technical Field

The present disclosure relates to electronic devices and a method of manufacturing electronic devices, including but not limited to semiconductor devices and a method of manufacturing semiconductor devices.

### 2. Related Art

Integration density of a semiconductor device is determined by an area occupied by a unit memory cell. As improvements in integration degree of semiconductor devices in which a memory cell is formed as a single layer on a substrate reaches a limit, three-dimensional semiconductor devices in which memory cells are stacked on a substrate are under development. Various structures and manufacturing methods are being developed to improve operation reliability of the semiconductor device.

### SUMMARY

According to an embodiment of the present disclosure, a semiconductor device may include a support structure including a plurality of first insulating layers alternately stacked with a plurality of second insulating layers, a gate structure including a plurality of conductive layers and including a first section positioned at a level corresponding to a level of the support structure and a second section positioned on the support structure, a contact plug extending through the gate structure and connected to a first conductive layer of the plurality of conductive layers, and a first support including a plurality of pillars extending between the first section and the support structure and extending through the second section, and a plurality of first protrusions protruding from the plurality of pillars into the support structure.

According to an embodiment of the present disclosure, a semiconductor device may include a support structure including a plurality of first insulating layers alternately stacked with a plurality of second insulating layers, a gate structure including a plurality of conductive layers and including a first section positioned at a level corresponding to a level of the support structure and a second section positioned on the support structure, a contact plug positioned on the support structure, extending through the gate structure, and connected to a first conductive layer of the plurality of conductive layers, a first support extending between the first section and the support structure and extending through the second section, and a second support spaced apart from the first support and extending through the gate structure.

According to an embodiment of the present disclosure, a method of manufacturing a semiconductor device may include forming a stack by alternately stacking a plurality of first material layers with a plurality of second material layers, forming a plurality of preliminary first support holes extending through the stack, forming a first support sacrificial layer in a corresponding one of the plurality of preliminary first support holes, forming a preliminary contact hole positioned in a region surrounded by the plurality of preliminary first support holes and extending through the stack and at least one of the plurality of second material layers is exposed through the preliminary contact hole, selectively removing the second material layers through the preliminary contact hole to form a plurality of first openings through which first openings the plurality of first support sacrificial layers are exposed, removing the plurality of first support sacrificial layers from the plurality of preliminary first support holes, thereby forming a plurality of first support holes, expanding the plurality of first support holes by selectively removing the plurality of second material layers through the plurality of first support holes, thereby forming an expanded first support hole, and forming a first support in the expanded first support hole.

### BRIEF DESCRIPTION OF THE DRAWINGS

FIG. 1A to FIG. 1C are drawings illustrating a semiconductor device according to an embodiment of the present disclosure.

FIG. 2A to FIG. 2C are drawings illustrating a semiconductor device according to an embodiment of the present disclosure.

FIG. 3A to FIG. 3C, FIG. 4A to FIG. 4C, FIG. 5A to FIG. 5C, FIG. 6A to FIG. 6C, FIG. 7A to FIG. 7C, FIG. 8A to FIG. 8C, and FIG. 9A to FIG. 9C are drawings illustrating a semiconductor device formed utilizing a method of manufacturing the semiconductor device according to an embodiment of the present disclosure.

### DETAILED DESCRIPTION

The cross-hatching throughout the figures illustrates corresponding or similar areas between the figures rather than indicating the materials associated with the areas. The drawings are not necessarily drawn to scale, and measurements of objects within a cross-section view are not necessarily proportionate to measurements of the same objects in corresponding plan views.

Terms such as “vertical,” “horizontal,” “under,” “on,” “sidewall,” “upper,” “lower,” “level,” and other terms implying relative spatial relationship or orientation are utilized only for the purpose of ease of description or reference to a drawing and are not otherwise limiting.

An embodiment of the present disclosure provides a semiconductor device and a method of manufacturing the semiconductor device having a stable structure and an improved characteristic.

According to the present disclosure, a semiconductor device having a stable structure and improved reliability may be provided.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in the present disclosure.

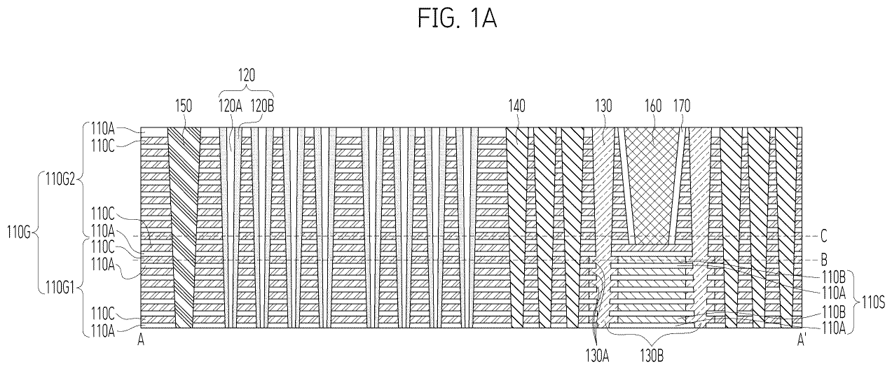

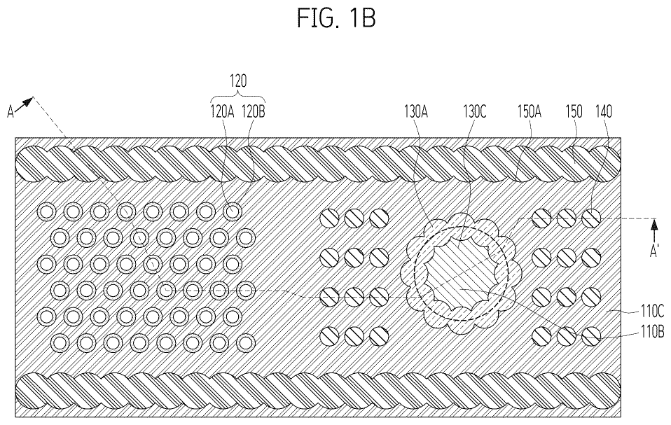

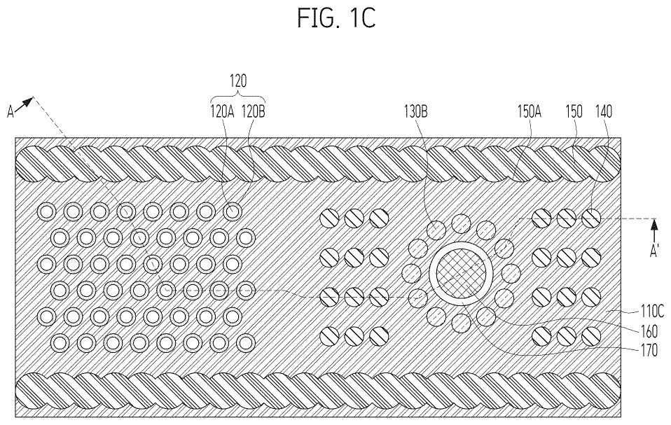

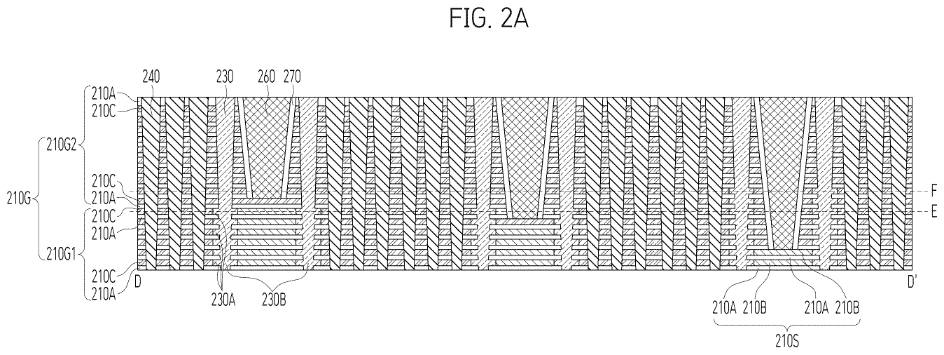

FIG. 1A to FIG. 1C are drawings illustrating a semiconductor device according to an embodiment of the present disclosure. FIG. 1A is a cross-sectional view taken along line A-A′ of FIG. 1B and FIG. 1C, FIG. 1B is a plan view at level B of FIG. 1A, and FIG. 1C is a plan view at level C of FIG. 1A.

Referring to FIG. 1A to FIG. 1C, the semiconductor device includes a support structure 110S, a gate structure 110G, channel structures 120, a first support 130, second supports 140, slit structures 150, a contact plug 160, and an insulating spacer 170.

The support structure 110S includes first insulating layers 110A alternately stacked with second insulating layers 110B. The support structure 110S supports a stack that forms the gate structure 110G during a process of forming the gate structure 110G.

A thickness of the first insulating layers 110A may be substantially equal to or different from a thickness of the second insulating layers 110B. For example, the thickness of the first insulating layers 110A may be substantially equal to the thickness of the second insulating layers 110B. Alternatively, the first insulating layers 110A may be thinner than the second insulating layers 110B. The first insulating layers 110A and the second insulating layers 110B may include different materials. For example, the first insulating layers 110A may include an insulating material such as an oxide, and the second insulating layers 110B may include an insulating material such as a nitride.

The gate structure 110G includes first insulating layers 110A alternately stacked with conductive layers 110C. The gate structure 110G includes a first section 110G1 positioned at a vertical level corresponding to or even with the vertical level of the support structure 110S and a second section 110G2 positioned on the first section 110G1 and the support structure 110S, where vertical is referenced with respect to the orientation of FIG. 1A. For example, the conductive layers 110C of the first section 110G1 are positioned at a levels corresponding to levels of the second insulating layers 110B of the support structure 110S.

The conductive layers 110C may be gate lines such as a source selection line, a word line, or a drain selection line. A source selection transistor, a memory cell, or a drain selection transistor may be positioned in a region where the channel structures 120 and the conductive layers 110C intersect. For example, one string may include at least one source selection transistor, a plurality of memory cells, and at least one drain selection transistor stacked along the channel structure 120. The first insulating layers 110A may include an insulating material such as an oxide. The conductive layers 110C may include a conductive material such as tungsten, molybdenum, or polysilicon.

The channel structures 120 extend through the gate structure 110G. Each of the channel structures 120 includes a channel layer 120A and a memory layer 120B surrounding the channel layer 120A. Each of the channel structures 120 may include an insulating core (not shown) within the channel layer 120A. The channel layer 120A may include a semiconductor material such as polysilicon or germanium. The insulating core may include an insulating material such as an oxide.

The contact plug 160 extends through the gate structure 110G and is connected to at least one of the conductive layers 110C. The contact plug 160 are positioned on or over the support structure 110S. The support structure 110S is positioned in a region near the contact plug 160 to prevent or reduce bending of the stack that forms the gate structure 110G under the contact plug 160. The contact plug 160 may include a conductive material such as tungsten.

The insulating spacer 170 surrounds a sidewall of the contact plug 160. The insulating spacer 170 insulates the contact plug 160 from conductive layers 110C except for the conductive layer 110C electrically connected to the contact plug 160. The insulating spacer 170 may include an insulating material such as an oxide.

The first support 130 extends through the gate structure 110G. During the process of forming the gate structure 110G, the first support 130 prevents or reduced bending of the stack that forms the gate structure 110G. The first support 130 may include first protrusions 130A and pillars 130B. For example, each of the first supports 130 includes the pillars 130B disposed between the first section 110G1 and the support structure 110S and extending through the second section 110G2 and includes the first protrusions 130A protruding from the pillars 130B into the support structure 110S.

The first protrusions 130A are interconnected in a plane and surround a closed region 130C. The support structure 110S is positioned within the closed region 130C. The second insulating layers 110B of the support structure 110S are positioned at levels corresponding to levels of the first protrusions 130A. The pillars 130B are spaced apart around the contact plug 160. In an embodiment, the pillars 103B are arranged at equal distances along a perimeter of a circle centered around the contact plug 160. The width of the first protrusions 130A in a horizontal direction with respect to the drawings is wider than a width of the channel structure 120. The pillars 130B may have a width substantially the same as the width of the channel structures 120. Widths are compared at substantially a same level in a vertical direction with respect to FIG. 1A. For example, widths may be compared at an upper surface of FIG. 1A. The first support 130 may include an insulating material such as an oxide.

The second supports 140 extend through the gate structure 110G. The second supports 140 are spaced apart from the first supports 130. During the process of forming the gate structure 110G, the second supports 140 prevent or reduce bending of a stack that forms the gate structure 110G. The second supports 140 may have a structure similar to structure of the channel structures 120. For example, each of the second supports 140 includes at least one of a dummy channel layer, a dummy memory layer surrounding the dummy channel layer, and a dummy insulating core within the dummy channel layer. Alternatively, the second supports 140 may include an insulating material such as an oxide. Alternatively, the second supports 140 may include a conductive layer such as tungsten and an insulating layer surrounding the conductive layer.

The slit structure 150 extends through the gate structure 110G in a horizontal direction with respect to the drawings. The slit structure 150 extends through the gate structure 110G and includes second protrusions 150A protruding into the gate structure 110G. The slit structure 150 may be used during the process of forming the gate structure 110G during a process of manufacturing the semiconductor device. The slit structure 150 may include an insulating material, a conductive material, or a semiconductor material.

The contact plug 160 is disposed on or over the support structure 110S The support structure 110S prevents or reduces bending of the stack that forms the gate structure 110G during the process of forming the gate structure 110G under the contact plug 160.

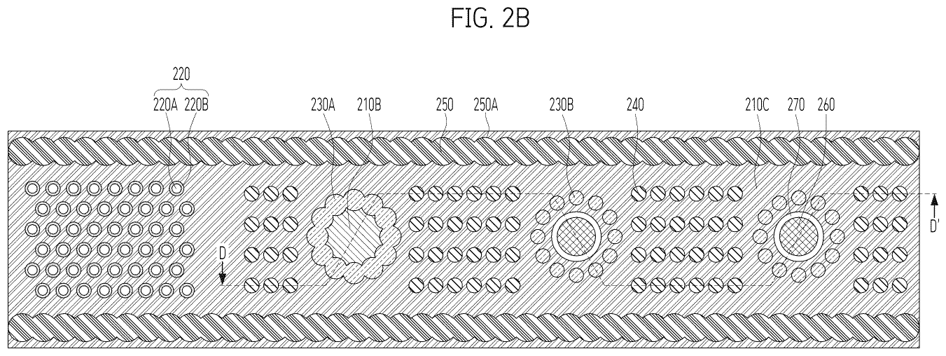

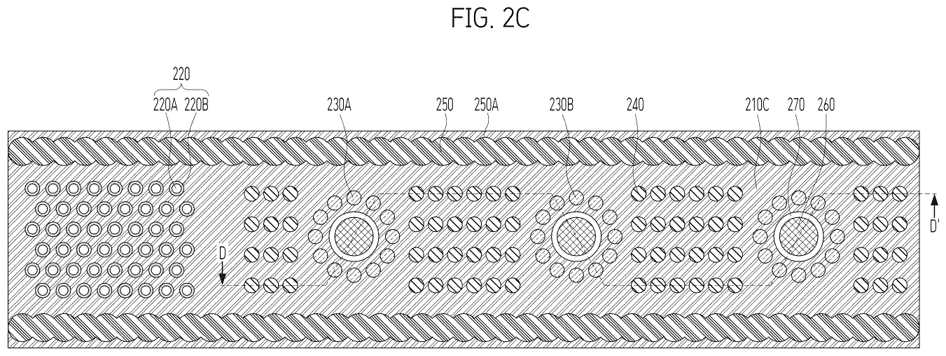

FIG. 2A to FIG. 2C are drawings illustrating a semiconductor device according to an embodiment of the present disclosure. FIG. 2A is a cross-sectional view taken along line D-D′ of FIG. 2B and FIG. 2C, FIG. 2B is a plan view at level E of FIG. 2A, and FIG. 2C is a plan view at level F of FIG. 2A.

Referring to FIG. 2A to FIG. 2C, the semiconductor device includes support structures 210S, a gate structure 210G, channel structures 220, first supports 230, second supports 240, slit structures 250, contact plugs 260, and insulating spacers 270.

Each of the support structures 210S includes first insulating layers 210A alternately stacked with second insulating layers 210B. The support structures 210S have different heights. For example, each of the support structures 210S includes different numbers of alternately stacked insulating layers 210A and 210B.

A thickness of each of the first insulating layers 210A may be different from a thickness of each of the second insulating layers 210B. For example, the first insulating layers 210A may be thinner than the second insulating layers 210B. The first insulating layers 210A and the second insulating layers 210B may include different materials. For example, the first insulating layers 210A may include an insulating material such as an oxide, and the second insulating layers 210B may include an insulating material such as a nitride.

The gate structure 210G includes first insulating layers 210A alternately stacked with conductive layers 210C. The gate structure 210G includes a first section 210G1 positioned at a vertical level corresponding to or even with the support structure 210S and a second section 210G2 positioned on the first section 210G1 and the support structure 210S, where vertical is referenced with respect to the orientation of FIG. 2A. For example, the conductive layers 210C of the first section 210G1 are positioned at a levels corresponding to levels of the second insulating layers 210B of the support structure 210S.

The channel structures 220 extend through the gate structure 210G. Each of the channel structures 220 includes a channel layer 220A and a memory layer 220B surrounding the channel layer 220A. The channel layer 220A may include a semiconductor material such as polysilicon or germanium.

The contact plugs 260 extend through the gate structure 210G and are each connected to one of the conductive layers 210C. The contact plugs 260 are positioned on or over corresponding support structures 210S. For example, each of the contact plugs 260 is positioned in a region near a corresponding support structures 210S. The number of the contact plugs 260 may be the same as the number of the support structures 210S. In this example, the contact plugs 260 have different heights, and the support structures 210S have different heights. The height of a contact plug 260 and the height of the corresponding support structure 210S is inversely proportional. For example, when the height of the contact plug 260 is smaller, the height of the corresponding support structure 210S is larger. The contact plug 160 may include a conductive material such as tungsten.

An insulating spacer 270 surrounds a sidewall of each of the contact plugs 260. The insulating spacer 270 insulates from the contact plug 260 conductive layers 210C except for the conductive layer 210C electrically connected to the contact plug 260. The insulating spacer 270 may include an insulating material such as an oxide.

The first supports 230 extend through the gate structure 210G. Each first support 230 includes a first protrusion 230A and a pillar 230B. For example, the first supports 230 include the pillars 230B disposed between the first section 210G1 and the support structure 210S and extending through the second section 210G2 and include the first protrusions 230A protruding from the pillars 230B into the support structure 210S.

The second supports 240 extend through the gate structure 210G. The second supports 240 are spaced apart from the first supports 230. The second supports 240 may have a structure similar to the structure of the channel structures 220. Alternatively, the second supports 240 includes an insulating material such as an oxide. Alternatively, the second supports 240 may include a conductive layer such as tungsten and an insulating layer surrounding the conductive layer.

The slit structure 250 extends through the gate structure 210G in a horizontal direction with respect to the drawings. The slit structure 250 extends through the gate structure 210G and includes second protrusions 250A protruding into the gate structure 210G. The slit structure 250 may include an insulating material, a conductive material, or a semiconductor material.

The contact plugs 260 are positioned on or over corresponding support structures 210S. For example, the number of the contact plugs 260 and the number of the support structures 210S may be the same, and the contact plugs 26 may be positioned in regions near the support structures 210S. By forming the support structures 210S at different heights corresponding to the contact plugs 260 having different heights, support may be improved under the contact plugs 260.

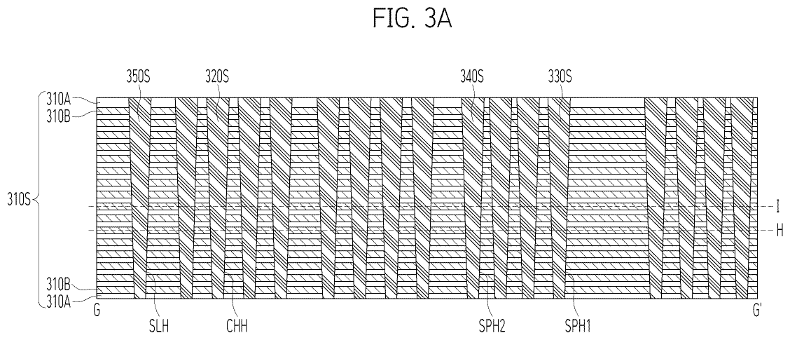

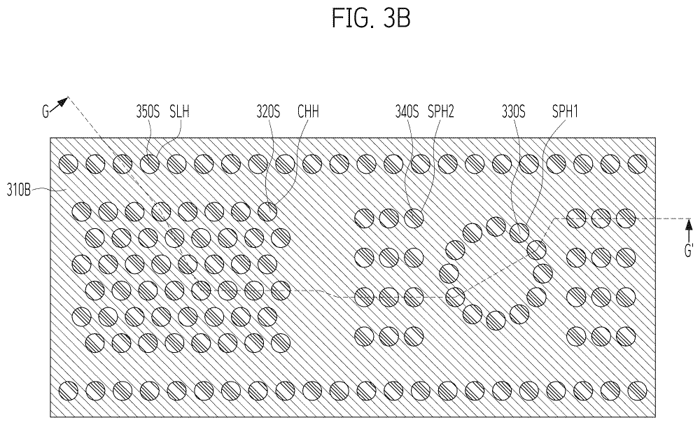

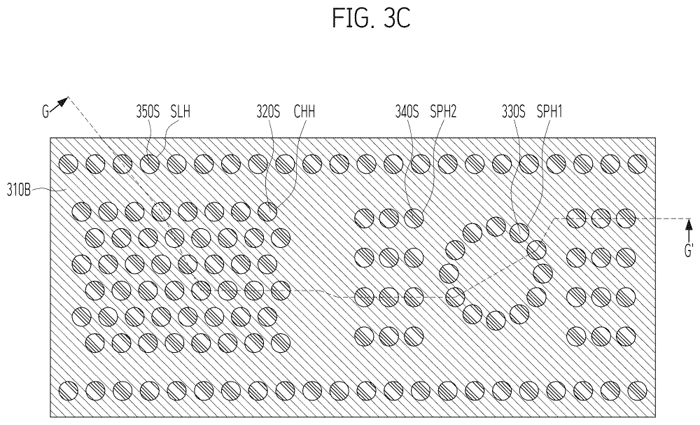

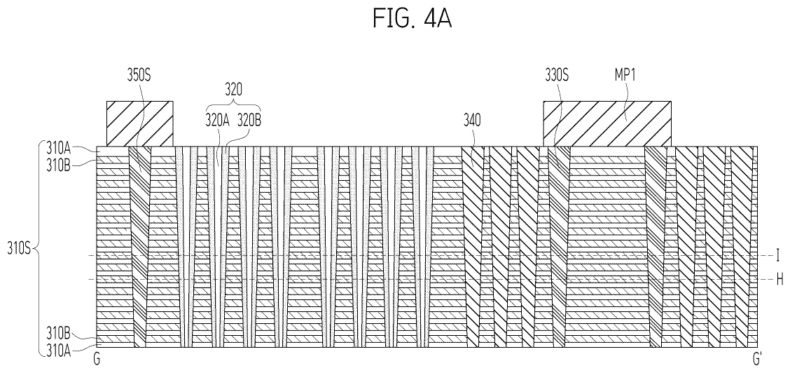

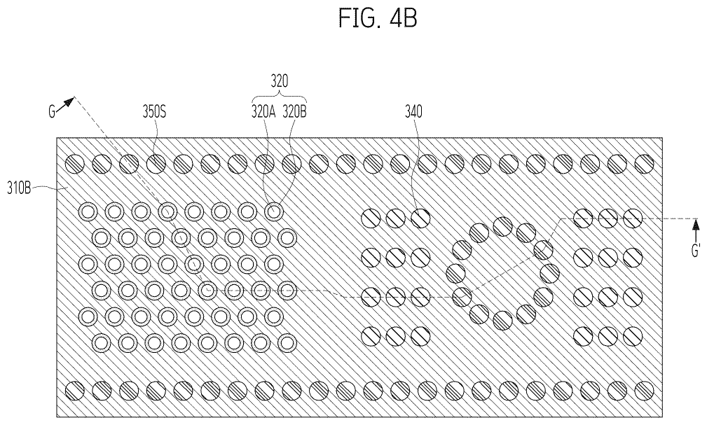

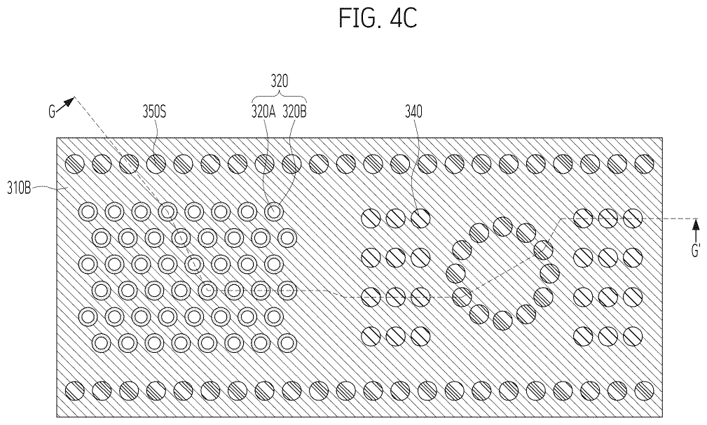

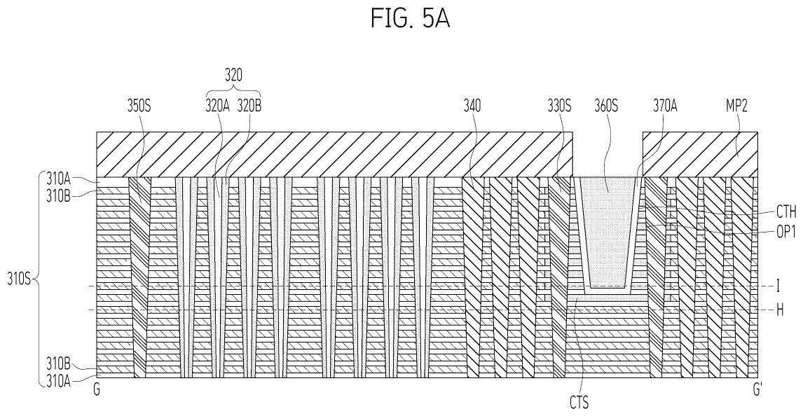

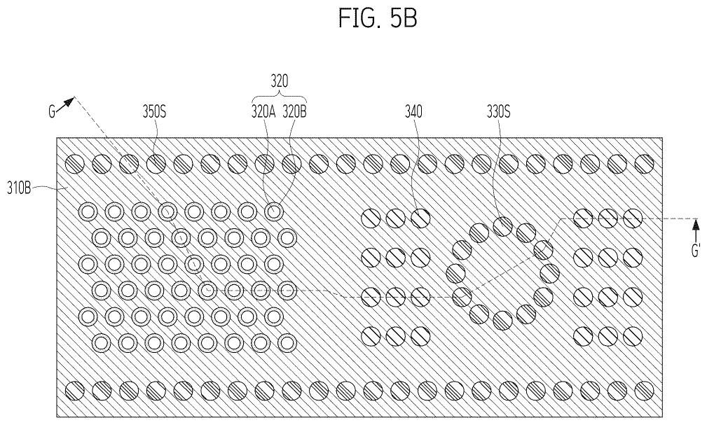

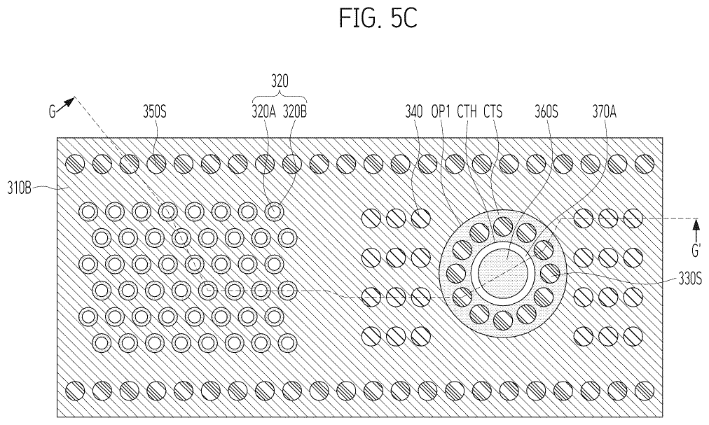

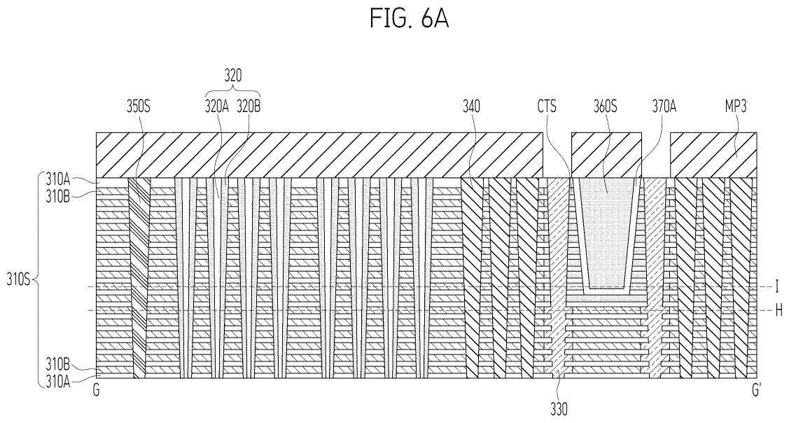

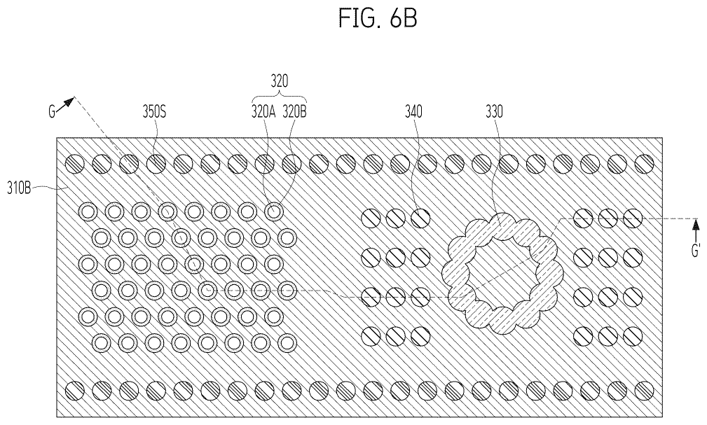

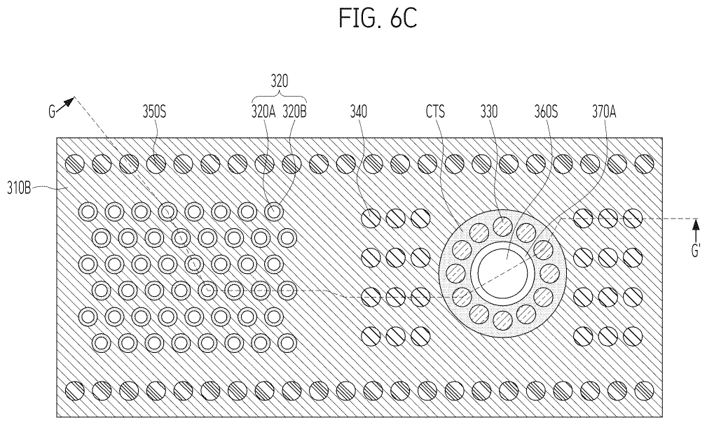

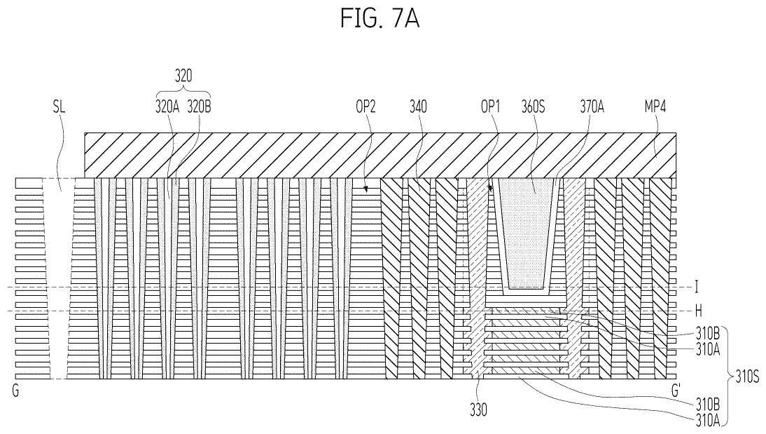

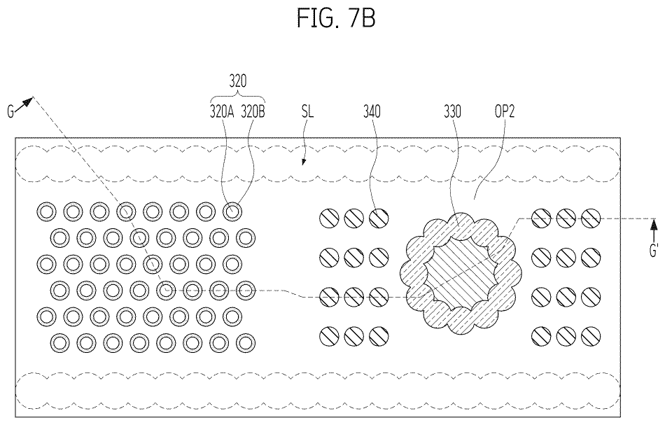

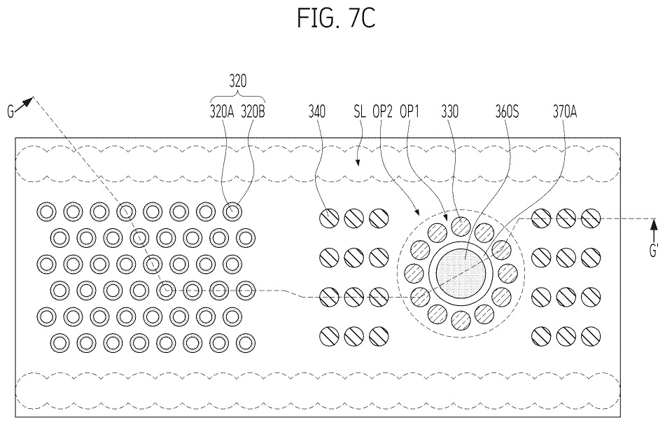

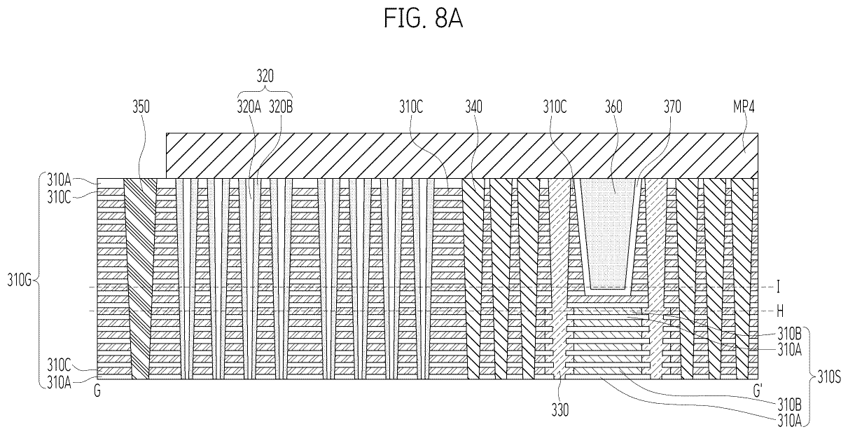

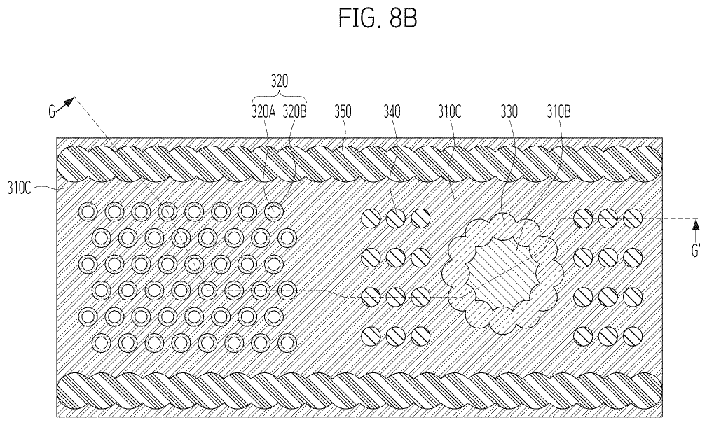

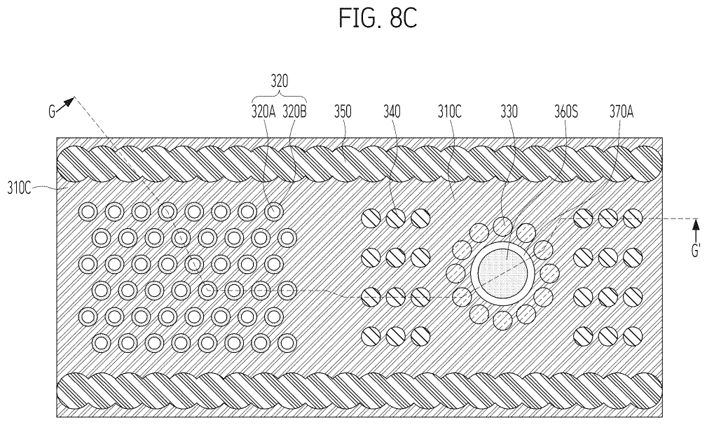

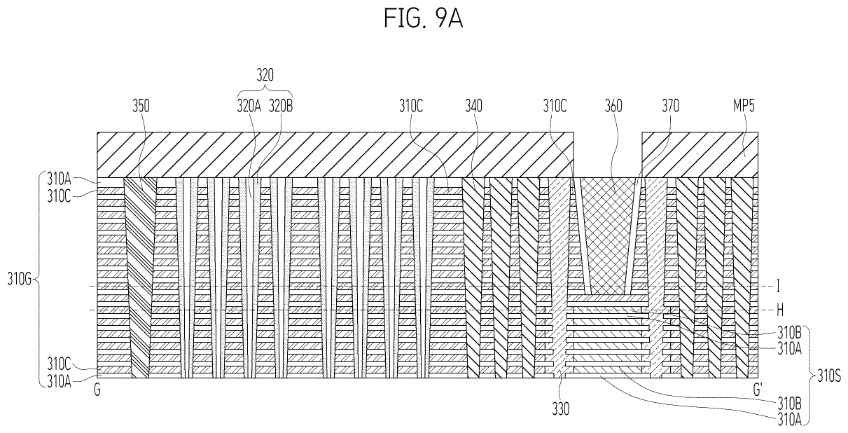

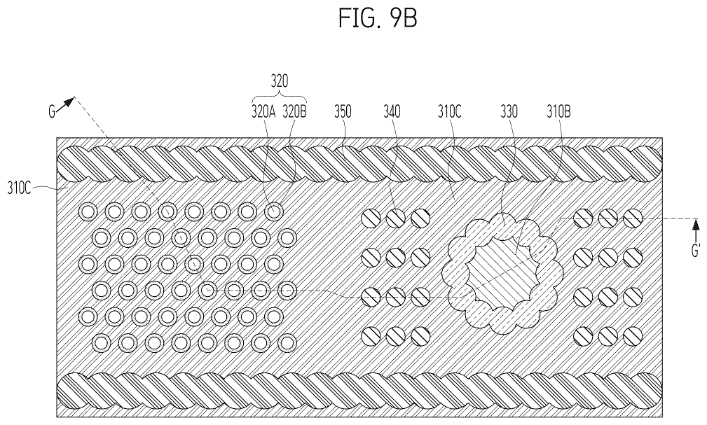

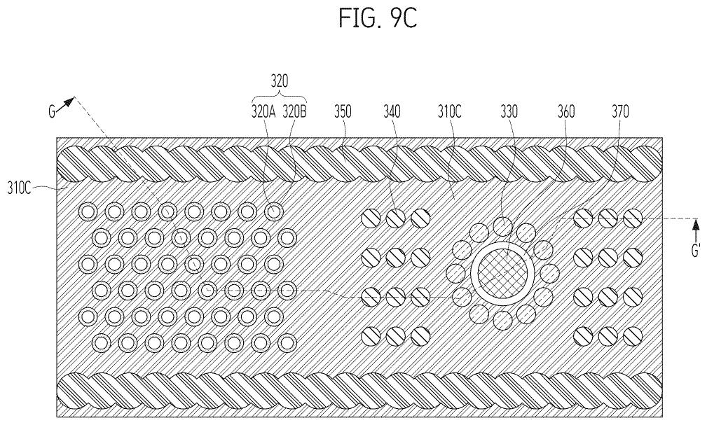

FIG. 3A to FIG. 3C, FIG. 4A to FIG. 4C, FIG. 5A to FIG. 5C, FIG. 6A to FIG. 6C, FIG. 7A to FIG. 7C, FIG. 8A to FIG. 8C, and FIG. 9A to FIG. 9C are drawings illustrating a semiconductor device formed utilizing a method of manufacturing the semiconductor device according to an embodiment of the present disclosure. FIG. 3A, FIG. 4A, FIG. 5A, FIG. 6A, FIG. 7A, FIG. 8A, and FIG. 9A are cross-sectional views taken along line G-G′ of FIG. 3B, FIG. 4B, FIG. 5B, FIG. 6B, FIG. 7B, FIG. 8B, and FIG. 9B, respectively, and FIG. 3C, FIG. 4C, FIG. 5C, FIG. 6C, FIG. 7C, FIG. 8C, and FIG. 9C, respectively. FIG. 3B, FIG. 4B, FIG. 5B, FIG. 6B, FIG. 7B, FIG. 8B, and FIG. 9B are plan views at level H of FIG. 3A, FIG. 4A, FIG. 5A, FIG. 6A, FIG. 7A, FIG. 8A, and FIG. 9A, respectively. FIG. 3C, FIG. 4C, FIG. 5C, FIG. 6C, FIG. 7C, FIG. 8C, and FIG. 9C are plan views at level I of FIG. 3A, FIG. 4A, FIG. 5A, FIG. 6A, FIG. 7A, FIG. 8A, and FIG. 9A, respectively.

Referring to FIG. 3A to FIG. 3C, a stack 310S is formed by alternately stacking first material layers 310A with second material layers 310B. A thickness of the first material layers 310A may be substantially equal to or less than a thickness of the second material layers 310B. For example, the thickness of the first material layers 310A may be substantially equal to the thickness of the second material layers 310B. Alternatively, the first material layers 310A may be thinner than the second material layers 310B. The first insulating layers 310A and the second insulating layers 310B may include different materials. For example, the first insulating layers 310A may include an insulating material such as an oxide, and the second insulating layers 310B may include an insulating material such as a nitride.

Preliminary channel holes CHH extending through the stack 310S are formed. Preliminary slit holes SLH extending through the stack 310S are formed. The preliminary slit holes SLH are arranged spaced apart from each other in a direction such as the horizontal direction with respect to FIG. 3A, FIG. 3B, and FIG. 3C. Preliminary first support holes SPH1 extending through the stack 310S are formed. The preliminary first support holes SPH1 are formed near a region where a contact plug is formed in a subsequent process. The region may be established by connecting centers of the preliminary first support holes SPH1.

Preliminary second support holes SPH2 extending through the stack 310S are formed. The preliminary second support holes SPH2 are formed spaced apart from the preliminary first support holes SPH1. When forming the channel holes CHH, the preliminary slit holes SLH, the preliminary first support holes SPH1, and/or the preliminary second support holes SPH2 may be formed. Manufacturing cost of the semiconductor device may be reduced by simultaneously forming holes for different structures in a single process.

Sacrificial materials are formed in the preliminary channel holes CHH, the preliminary slit holes SLH, the preliminary first support holes SPH1, and the preliminary second support holes SPH2. Channel sacrificial layers 320S are formed in the channel holes CHH. First support sacrificial layers 330S are formed in the preliminary first support holes SPH1. Second support sacrificial layers 340S are formed in the preliminary second support holes SPH2. Slit sacrificial layers 350S are formed in the preliminary slit holes SLH. The sacrificial materials may include material such as carbon.

Referring to FIG. 4A to FIG. 4C, a first mask pattern MP1 is formed covering the first support sacrificial layers 330S, and the second support sacrificial layers 340S (of FIG. 3A to FIG. 3C) are exposed through openings in the first mask pattern MP1. For example, the first mask pattern MP1 is formed covering the first support sacrificial layers 330S and the slit sacrificial layers 350S, and the channel sacrificial layers 320S and the second support sacrificial layers 340S (of FIG. 3A to FIG. 3C) are exposed through openings in the first mask pattern MP1.

Channel structures 320 are formed. The channel sacrificial layers 320S are removed through openings in the first mask pattern MP1, forming channel holes in substantially the same location as the preliminary channel holes CHH. A memory layer 320B and a channel layer 320A of the channel structures 320 are formed in the channel holes. For example, the memory layer 320B and the channel layer 320A may be sequentially formed in the channel holes.

Second supports 340 are formed. The second support sacrificial layers 340S are removed through openings in the first mask pattern MP1, forming second support holes in substantially the same location as the preliminary second support holes SPH2. Each of the second supports 340 is formed in a corresponding second support hole. The first mask pattern MP1 is removed.

The second supports 340 may be formed when forming the channel structures 320. The second supports 340 may have a structure similar to the channel structures 320. For example, the second supports 340 may have a dummy memory layer and a dummy channel layer. The present disclosure is not limited to this example, and the second supports 340 may include a material different from the material of the channel structures 320. The second supports 340 may include an insulating material such as an oxide. Alternatively, the second supports 340 may include a conductive layer such as tungsten and an insulating layer covering the conductive layer.

Referring to FIG. 5A to FIG. 5C, a second mask pattern MP2 is formed covering the stack 310S including the first support sacrificial layers 330S. A region surrounded by the first support holes SPH1 is exposed through an opening in the second mask pattern MP2.

For example, the second mask pattern MP2 is formed covering the channel structures 320, the first support sacrificial layers 330S, the second supports 340, and the slit sacrificial layers 350S, and the region surrounded by the first support holes SPH1 is exposed through an opening in the second mask pattern MP2.

A preliminary contact hole CTH is formed. For example, the preliminary contact hole CTH may be formed by etching the stack 310S using the second mask pattern MP2 as an etching barrier. At least one of the second material layers 310B is exposed through the preliminary contact hole CTH.

Preliminary first openings OP1 are formed. Selectively removing the second material layers 310B through contact hole CTH exposes the first support sacrificial layers 330S and forms the preliminary first openings OP1. Sacrificial layers CTS are formed in the preliminary first openings OP1. The sacrificial layers CTS may include a material having an etching selectivity ratio with respect to the first material layers 310A and the second material layers 310B. Alternatively, the sacrificial layers CTS may include a material having an etching selectivity ratio with respect to the first support sacrificial layers 330S. For example, the sacrificial layers CTS may include polysilicon.

A preliminary insulating spacer 370A is formed within the preliminary contact hole CTH. A contact sacrificial layer 360S is formed within the preliminary insulating spacer 370A. The preliminary insulating spacer 370A may include an insulating material such as an oxide, and the contact sacrificial layer 360S may include a sacrificial material such as carbon. The second mask pattern MP2 is removed.

Referring to FIG. 6A to FIG. 6C, a third mask pattern MP3 is formed covering the contact hole CTH, and the first support sacrificial layers 330S are exposed through openings in the third mask pattern MP3. For example, the third mask pattern MP3 is formed covering the channel structures 320, the second supports 340, the slit sacrificial layer 350S, and the contact sacrificial layer 360, and the first support sacrificial layers 330S (see FIG. 5A through FIG. 5C) are exposed through openings in the third mask pattern MP3.

The first support sacrificial layers 330S are removed through openings in the third mask pattern MP3, forming first support holes in substantially the same location as the preliminary first support holes SPH1. The first support holes are expanded by selectively removing some of the second material layers 310B through the first support holes SPH1. The first support holes SPH1 are expanded such that the first support holes are interconnected, such as shown in FIG. 6B. One expanded first support hole is formed by expanding the first support holes such that the second material layers 310B are isolated under the preliminary contact hole CTH in the region surrounded by the first support holes. A region surrounded by the first support holes and positioned under the contact hole CTH is referred to as a closed region.

A first support 330 is formed in the expanded first support hole. For example, the first support 330 is formed by forming an insulating material such as an oxide in the expanded first support hole. The third mask pattern MP3 is removed.

Referring to FIG. 7A to FIG. 7C, a fourth mask pattern MP4 is formed covering the contact sacrificial layer 360S and the first support 330, and the slit sacrificial layers 350S are exposed through openings in the third mask pattern MP4. For example, the fourth mask pattern MP4 is formed covering the channel structures 320, the first support 330, the second supports 340, the contact sacrificial layer 360S, and the preliminary insulating spacer 370A, and the slit sacrificial layers 350S (see FIG. 6A through FIG. 6C) are exposed through openings in the third mask pattern MP3.

The slit sacrificial layers 350S are removed through openings in the fourth mask pattern MP4, forming slit holes in substantially the same location as the preliminary slit holes SLH. A slit SL is formed by expanding the slit holes in a vertical direction with respect to the drawings in FIG. 7B and FIG. 7C such that the slit holes are interconnected. The slit SL may be formed by etching the stack 310S using the fourth mask pattern MP4 as an etching barrier.

The second material layers 310B are removed through the slit SL, forming second openings OP2 in substantially the same location where the second material layers 310B were formed, through which second openings OP2 the sacrificial layers CTS are exposed. The contact sacrificial layers CTS are removed through the second openings OP2, forming first openings OP1 in substantially the same location where the preliminary first openings OP1 were formed. The stack 310S remains in the region surrounded by the first support holes, thus, the second material layers 310B remain in the closed region. The first material layers 310A alternately stacked with the second material layers 310B under the contact hole CTH are referred to as a support structure. The stack 310S is referred to as the support structure.

Referring to FIG. 8A to FIG. 8C, a gate structure 310G is formed. Third material layers 310C are formed in the first openings OP1 and the second openings OP2. For example, the third material layers 310C may be formed by disposing a conductive material such as tungsten in the first openings OP1 and the second openings OP2. Each of the third material layers 310C may be used as a gate line. Accordingly, the gate structure 310G is formed including the first material layers 310A alternately stacked with the third material layers 310C.

The height of the stack 310S may be increased to improve integration density of a semiconductor device. The first material layers 310A may be thinner than the second material layers 310B. As the height of the stack 310S increases, a target depth increases for the contact hole CTH with which is formed a contact plug connected to at least one of the third material layers 310C of the gate structure 310G, and a width of the contact hole CTH increases. When supports are not formed under the contact hole CTH, the stack 310S may not be sufficiently supported under the contact hole CTH.

During a process of manufacturing the semiconductor device, the second openings OP2 are formed by removing the second material layers 310B to form the gate structure 310G. Because the first material layers 310A are thinner than the second material layers 310B, when the second material layers 310B are removed, the stack 310S may be susceptible to bending. As a region where the contact hole CTH is formed increases in size, because a region decreases in size where the second supports 340 supporting the stack 310S are formed, the stack 310S may be susceptible to bending during a process of forming the gate structure 310G.

According to an embodiment of the present disclosure, the preliminary first support holes SPH1 are formed near a region where the contact hole CTH is formed. Because a support structure 330 is formed in the first support holes under the contact hole CTH, the preliminary first support holes SPH1 are formed to surround the contact hole CTH. The first support holes are expanded such that the first support holes are interconnected, forming a closed region, and the stack 310S remains in the closed region. The stack 310S that remains in the closed region is used as a support structure. As a result, bending of the stack 310S may be prevented or reduced because the stack 310S remains under the contact hole CTH during a process of removing the second material layers 310B to form the gate structure 310G.

A slit structure 350 is formed in the slit SL. The slit structure 350 may include an insulating material, a conductive material, a semiconductor material, or the like. The fourth mask pattern MP4 is removed.

Referring to FIG. 9A to FIG. 9C, a fifth mask pattern MP5 is formed covering the first support 330, and the contact sacrificial layer 360S are exposed through an opening in the fifth mask pattern MP5. For example, the fifth mask pattern MP5 is formed covering the channel structures 320, the first support 330, the second supports 340, and the slit structure 350, and the contact sacrificial layer 360S and the preliminary insulating spacer 370A (see FIG. 8A through FIG. 8C) are exposed through an opening in the fifth mask pattern MP5.

The contact sacrificial layer 360S is removed using the fifth mask pattern MP5 as an etching barrier, forming a contact hole in substantially the same location as the preliminary contact hole CTH. The third material layer 310C is exposed by etching a lower surface of the preliminary insulating spacer 370A. The remaining material from the preliminary insulating spacer 370A forms an insulating spacer 370 that surrounds a sidewall of the contact plug. A contact plug 360 is formed in the contact hole. The contact plug 360 may be formed including a conductive material such as tungsten. The fifth mask pattern MP5 is removed.

The example illustrated in the drawings shows one contact plug 360, but the quantity of contact plugs 360 is not limited to one. For example, the quantity of contact plugs may be the same as the quantity of third material layers 310C. Each contact plug is formed having a different height and is connected to a corresponding third material layer 310C. A support structure may be formed under each contact plug.

According to the manufacturing method, the first support holes are formed near a region where the contact hole is formed, and the first support holes are expanded such that the first support holes are interconnected. The stack 310S remains in the region surrounded by the expanded first support holes, and the remaining stack 310S forms a support structure preventing the stack 310S from bending during the process of forming the gate structure 310G.

Although the detailed embodiments are described in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor device comprising:
a support structure including a plurality of first insulating layers alternately stacked with a plurality of second insulating layers;
a gate structure including a plurality of conductive layers and including a first section positioned at a level corresponding to a level of the support structure and a second section positioned on the support structure;
a contact plug extending through the gate structure and connected to a first conductive layer of the plurality of conductive layers; and
a first support including a plurality of pillars extending between the first section and the support structure and extending through the second section and a plurality of first protrusions protruding from the plurality of pillars into the support structure.

2. The semiconductor device of claim 1, wherein the plurality of first protrusions are interconnected in a plane and surround a closed region.

3. The semiconductor device of claim 2, wherein the plurality of second insulating layers are positioned at a level corresponding to a level of the plurality of first protrusions and are positioned in the closed region.

4. The semiconductor device of claim 1, wherein the plurality of pillars are spaced apart from each other around the contact plug.

5. The semiconductor device of claim 4, further comprising:
a channel structure extending through the gate structure; and
a second support extending through the gate structure.

6. The semiconductor device of claim 5, wherein the plurality of pillars have substantially a same width as a width of the channel structure.

7. The semiconductor device of claim 5, wherein the second support has substantially a same width as a width of the channel structure.

8. The semiconductor device of claim 1, further comprising a channel structure extending through the gate structure.

9. The semiconductor device of claim 8, wherein a width of one of the plurality of first protrusions is wider than a width of the channel structure.

10. The semiconductor device of claim 1, further comprising a slit structure extending through the gate structure and including a plurality of second protrusions protruding into the gate structure.

11. The semiconductor device of claim 1, wherein each of the plurality of first insulating layers is thinner than one of the plurality of second insulating layers or one of the plurality of conductive layers.

12. A semiconductor device comprising:
a support structure including a plurality of first insulating layers alternately stacked with a plurality of second insulating layers;
a gate structure including a plurality of conductive layers and including a first section positioned at a level corresponding to a level of the support structure and a second section positioned on the support structure;
a contact plug positioned on the support structure, extending through the gate structure, and connected to a first conductive layer of the plurality of conductive layers;
a first support extending between the first section and the support structure and extending through the second section; and
a second support spaced apart from the first support and extending through the gate structure.

13. The semiconductor device of claim 12, wherein the first support includes a plurality of pillars extending between the first section and the support structure and extending through the second section, and a plurality of first protrusions protruding from the each of the plurality of pillars into the support structure.

14. The semiconductor device of claim 13, wherein the plurality of first protrusions are interconnected in a plane and surround a closed region.

15. The semiconductor device of claim 14, wherein the plurality of second insulating layers are positioned at a level corresponding to a level of the plurality of first protrusions and are positioned within the closed region.

16. The semiconductor device of claim 13, wherein the plurality of pillars are spaced apart from each other around the contact plug.

17. The semiconductor device of claim 13, further comprising a channel structure extending through the gate structure.

18. The semiconductor device of claim 17, wherein a width of one of the plurality of pillars is substantially the same as a width of the channel structure.

19. The semiconductor device of claim 17, wherein a width of one of the plurality of first protrusions is wider than a width of the channel structure.

20. The semiconductor device of claim 17, wherein a width of the second support is substantially the same as a width of the channel structure.

21. The semiconductor device of claim 12, further comprising a slit structure extending through the gate structure and including a plurality of second protrusions protruding into the gate structure.

22. The semiconductor device of claim 12, wherein one of the plurality of first insulating layers is thinner than one of the plurality of second insulating layers or one of the plurality of conductive layers.
